(19) United States
(12) Patent Application Publication
(10) Pub. No.: US 2026/0129850 A1
(43) Pub. Date: May 7, 2026

(54) READ-ONLY MEMORY DEVICE AND METHOD

(71) Applicant: TAIWAN SEMICONDUCTOR MANUFACTURING COMPANY, LTD., Hsinchu (TW)

(72) Inventors: Ji-Kuan LEE, Hsinchu (TW); Yao-Jen YANG, Hsinchu (TW); Chia-En HUANG, Hsinchu (TW); Ting-Wei CHIANG, Hsinchu (TW)

(21) Appl. No.: 18/937,608

(22) Filed: Nov. 5, 2024

(51) Int. Cl. H10B 20/00

(52) U.S. Cl. CPC H10B 20/363

(57) ABSTRACT

An IC device includes a first transistor including a first gate coupled to a first word line and including a first work function configuration, a first metal-like defined (MD) segment adjacent to the first gate and coupled to one of a bit line or reference line, and a second MD segment adjacent to the first gate and coupled to the other of the bit line or the reference line, and a second transistor including a second gate coupled to a second word line and including a second work function configuration different from the first work function configuration, the second MD segment adjacent to the second gate, and a third MD segment adjacent to the second gate and coupled to the one of the bit line or the reference line.

### BACKGROUND

The ongoing trend in miniaturizing integrated circuits (ICs) has resulted in progressively smaller devices which consume less power, yet provide more functionality at higher speeds than earlier technologies. Such miniaturization has been achieved through design and manufacturing innovations tied to increasingly strict specifications. Various electronic design automation (EDA) tools are used to generate, revise, and verify designs for semiconductor devices while ensuring that IC structure design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory circuit, in accordance with some embodiments.

FIGS. 2A-2D are a plan view, side view, and cross-sectional views of an IC device and layout diagram, in accordance with some embodiments.

FIGS. 3A-3D are a plan view, side view, and cross-sectional views of an IC device and layout diagram, in accordance with some embodiments.

FIGS. 4A-4D are a plan view, side view, and cross-sectional views of an IC device and layout diagram, in accordance with some embodiments.

FIG. 5A depicts memory circuit operating parameters, in accordance with some embodiments.

FIGS. 5B-5D are cross-sectional views of IC structures and layout diagrams, in accordance with some embodiments.

FIG. 6 is a flowchart of a method of operating a memory circuit, in accordance with some embodiments.

FIG. 7 is a flowchart of a method of manufacturing an IC device, in accordance with some embodiments.

FIG. 8 is a flowchart of a method of generating an IC layout diagram, in accordance with some embodiments.

FIG. 9 is a block diagram of an IC layout diagram generation system, in accordance with some embodiments.

FIG. 10 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) device, read-only memory (ROM) circuit, and corresponding methods include a transistor having one of a predetermined number of work function configurations. The multiple work function configurations, and in some embodiments threshold voltages corresponding to the work function configurations, represent encoding levels such that a ROM circuit is capable of determining the encoding levels by detecting the work function configurations, e.g., by detecting the threshold voltages, of single IC device transistors and outputting a plurality of bits based on the encoding levels.

The IC device is thereby capable of having increased coding density by providing multi-level coding in a smaller area compared to other approaches, e.g., those in which in which a single transistor location is used to represent binary encoding levels based on the presence or absence of a working transistor. Because the IC device includes a working transistor at each transistor location, the IC device is also less susceptible to being decoded through reverse engineering, e.g., by optics methods, compared to other approaches, and is thereby capable of providing increased coding security.

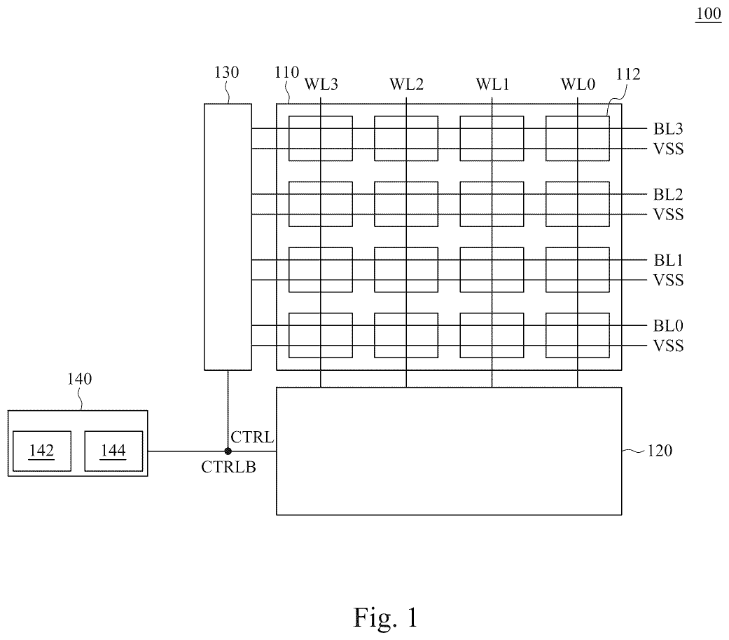

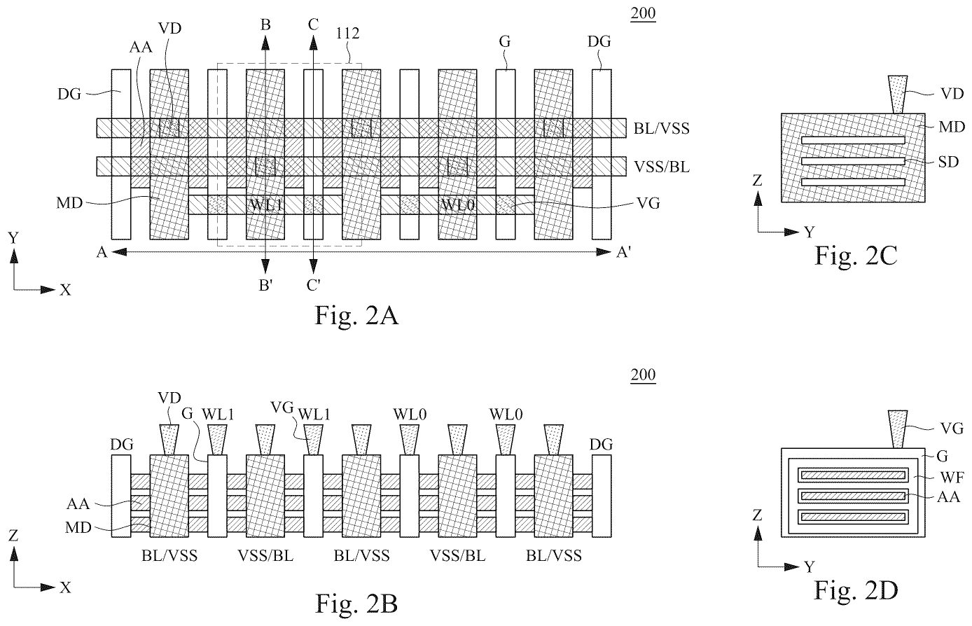

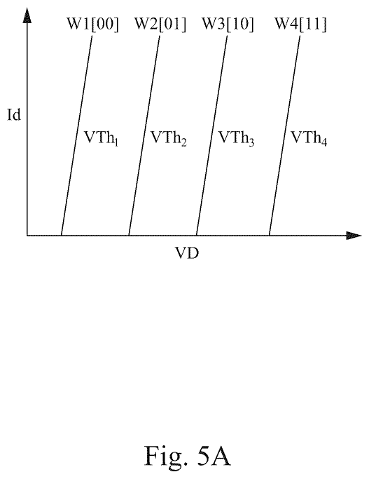

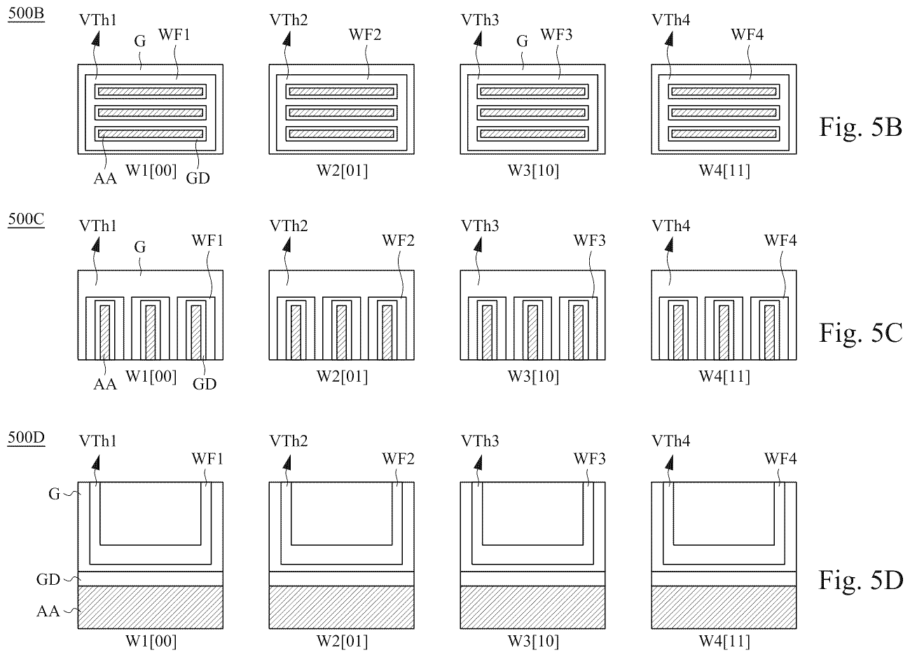

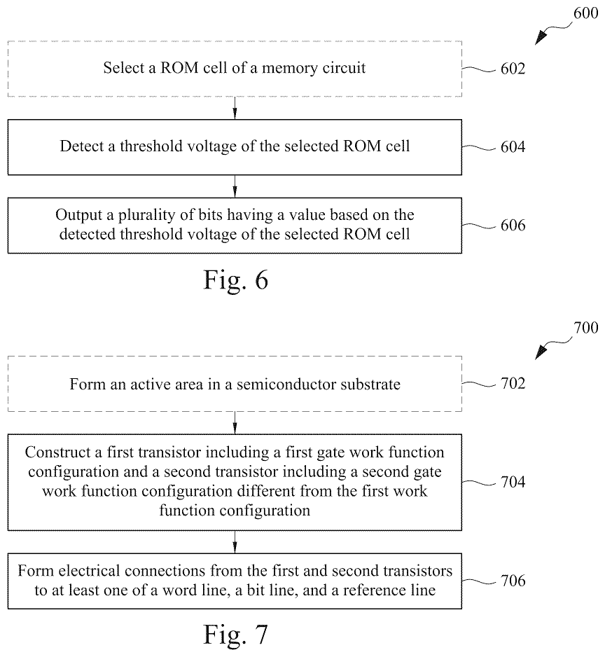

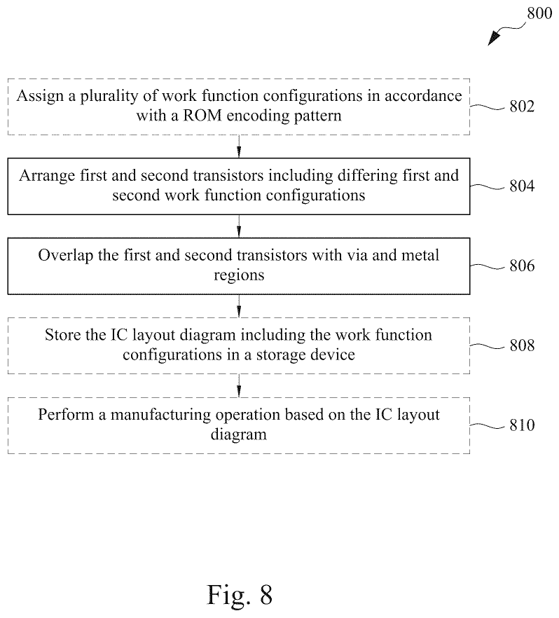

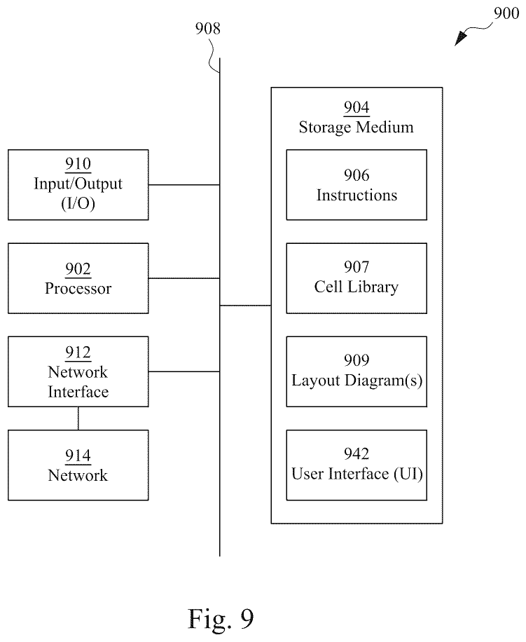

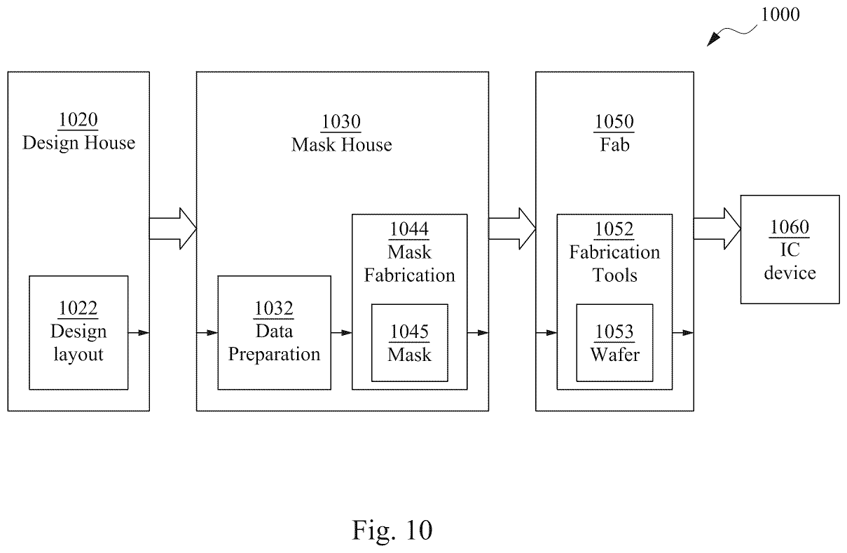

As discussed below, in accordance with various embodiments, FIG. 1 is a schematic diagram of a memory circuit 100, FIGS. 2A-2D, 3A-3D, and 4A-4D are plan, side, and cross-sectional views of corresponding IC devices and layout diagrams 200-400, FIG. 5A depicts memory circuit operating parameters, FIGS. 5B-5D are cross-sectional views of IC structures and IC layout diagrams 500B-500D, FIG. 6 is a flowchart of a method 600 of operating a memory circuit, FIG. 7 is a flowchart of a method 700 of manufacturing a memory circuit, and FIG. 8 is a flowchart of a method 800 of generating an IC layout diagram, e.g., using an IC layout diagram generation system 900 depicted in FIG. 9 and/or in accordance with an IC manufacturing flow 1000 depicted in FIG. 10.

FIGS. 1-5D are simplified for the purpose of illustration. In some embodiments, one or more of memory circuit 100, IC devices/layout diagrams 200-400, or IC structures/layout diagrams 500B-500D includes features in addition to those depicted in FIGS. 1-5D, e.g., a global control and/or input/output (I/O) circuit configured to generate. propagate, and/or receive one or more signals including and/or in addition to those discussed below. Some circuit elements depicted in FIGS. 1-5D include corresponding input and/or output terminals that are not labeled for the purpose of clarity.

FIG. 1 is a diagram of memory circuit 100, in accordance with some embodiments. In some embodiments, memory circuit 100 is some or all of an IC. In some embodiments, memory circuit 100 is included in another IC circuit and/or package, e.g., a digital circuit, an analog circuit, a compute in memory (CIM) circuit, a system-on-chip (SOC), a circuit positioned in a fan-out, 3D, 2.5D, or other IC package, and/or other suitable circuit.

Memory circuit 100 includes an array 110 of memory cells 112 coupled to a word line driver 120 and a read interface 130, and a control circuit 140 coupled to word line driver 120 and R/W interface 130 through a control signal bus CTRLB. Memory circuit 100 is configured to be capable of executing some or all of a method, e.g., method 600 discussed below with respect to FIG. 6, in which data are read from one or more instances of memory cell 112, as discussed below.

The arrangement and orientation of the memory circuit 100 features depicted in FIG. 1 are non-limiting examples provided for the purpose of illustration. Arrangements and orientations other than those depicted in FIG. 1 are within the scope of the present disclosure.

Two or more circuit elements are considered to be coupled based on one or more direct signal connections and/or one or more indirect signal connections that include one or more logic devices, e.g., an inverter or logic gate, between the two or more circuit elements. In some embodiments, signal communications between the two or more coupled circuit elements are capable of being modified, e.g., inverted or made conditional, by the one or more logic devices.

In the embodiment depicted in FIG. 1, memory circuit 100 is configured as a ROM circuit including memory cells 112 configured as ROM cells in which data are stored as part of the manufacturing process used to construct memory circuit 100, e.g., in accordance with method 700 discussed below with respect to FIG. 7, based on one or more IC layout diagrams, e.g., generated in accordance with method 800 discussed below with respect to FIG. 8.

Array 110 includes memory cells 112 (a single instance labeled for clarity) arranged in rows and columns (not labeled). Each memory cell 112 is coupled to one of word lines WL0-WL3 and one each of bit lines BL0-BL3 and instances of a reference line VSS.

For clarity, in addition to the corresponding word, bit, and reference lines, reference designators WL0-WL3 also represent word line signals, reference designators BL0-BL3 also represent bit line signals, and reference designator VSS also represents a reference voltage level VSS, e.g., ground, in some embodiments, as discussed below.

In the embodiment depicted in FIG. 1, array 110 includes total numbers of rows and columns equal to four for the purpose of illustration. In various embodiments, array 110 includes total numbers of rows and/or columns fewer or greater than four.

In the embodiment depicted in FIG. 1, array 110 includes the rows and columns arranged along respective row and column dimensions (not labeled). In some embodiments, array 110 has a three-dimensional (3D) arrangement, also referred to as a stacked arrangement, that includes one or more array layers (not shown) arranged perpendicularly to the row and column dimensions of the single layer depicted in FIG. 1 such that array 110 includes rows and columns in addition to those depicted in FIG. 1.

In the embodiment depicted in FIG. 1, each memory cell 112 is a three-terminal transistor device including at least one gate coupled to a corresponding one of word lines WL0-WL3, at least one source/drain (S/D) terminal coupled to one of bit lines BL0-BL3, and at least one S/D terminal coupled to one of reference lines VSS. In some embodiments, one or more of memory cells 112 includes a fourth terminal, e.g., a bulk or body terminal coupled to one of reference lines VSS.

In some embodiments, memory circuit 100 includes one or more signal lines in addition to or different from those depicted in FIG. 1, e.g., one or more control or power supply voltage lines. In some embodiments, one or more memory cells 112 includes one or more terminals in addition to or instead of those discussed above.

In some embodiments, a transistor device of a given memory cell 112 includes a planar transistor, a fin field-effect transistor (FinFET), a gate-all-around (GAA) transistor, e.g., having a nanosheet configuration, or another suitable configuration including at least one gate. In various embodiments, a transistor device of a given memory cell 112 includes an n-type transistor or a p-type transistor. In various embodiments, each memory cell 112 is included in one of IC devices 200-400, discussed below with respect to FIGS. 2A-4D, and/or includes at least one of one of gate structures 500B-500D, discussed below with respect to FIGS. 5A-5D.

As discussed below, each memory cell 112 includes the at least one gate having one work function configuration of a plurality of a predetermined number of work function configurations, e.g., a work function configuration WF or WF1-WF4 discussed below with respect to FIGS. 2A-5D. In some embodiments, each memory cell 112 thereby includes a transistor having one of a predetermined number of threshold voltages corresponding to the work function configurations.

In some embodiments, the total number of work function configurations is the same as the total number of threshold voltages. In some embodiments, the total number of work function configurations is greater than the total number of threshold voltages based on more than one work function configuration corresponding to a given threshold voltage.

In various embodiments, a given work function configuration includes one or more layers of work function materials positioned within a transistor gate electrode adjacent to one or more dielectric materials configured to electrically isolate the gate electrode from one or more channel regions of the active area included in the transistor.

The one or more layers of work function materials include n-type and/or p-type work function materials having one or more thicknesses, concentration levels, dopants, impurities, or the like, configured to increase or decrease a work function of the gate electrode by a target value compared to a work function of an equivalent gate electrode that does not include the one or more layers of work function materials. Non-limiting examples of work function materials include Ti, Ag, Al, TaAl, TaAlC, TiAlN, TaC, TaCN, TaSiN, Mn, and Zr.

A threshold voltage of a transistor is a function of operating conditions, e.g., voltage bias levels and/or temperature, in combination with the work function of the corresponding gate electrode. For a predetermined set of operating conditions, e.g., within predetermined voltage and/or temperature ranges, a given target value of the work function increase or decrease translates to an increase or decrease in the threshold voltage of the transistor that includes the corresponding gate compared to a threshold voltage of an equivalent transistor having the equivalent gate electrode that does not include the one or more layers of work function materials.

Each work function configuration thereby corresponds to a predetermined threshold voltage of the corresponding transistor such that the plurality of work function configurations is usable to define the predetermined number of threshold voltages.

As the total number of threshold voltages increases, the corresponding number of encoding levels of each memory cell 112 increases, thereby increasing the encoding density of each memory cell 112. In some embodiments, as the total number of threshold voltages increases, one or more differences between threshold voltages decrease and/or an overall span of threshold voltages increases, thereby potentially compromising an ability to reliably detect each threshold voltage of the total number of threshold voltages.

In some embodiments, the total number of threshold voltages ranges from two to 32. In some embodiments, the total number of threshold voltages is equal to four, eight, or 16. In some embodiments, the total number of threshold voltages is greater than 32.

Word line driver 120 is an electronic circuit configured to output word line signals WL0-WL3 on respective word lines WL0-WL3, responsive to one or more of control signals CTRL received from control circuit 140 on control signal bus CTRLB and/or from one or more circuits (not shown) external to memory circuit 100.

In some embodiments, a signal, e.g., a control signal CTRL, is a time-based series of transitions between high and low voltage levels, e.g., corresponding to high and low logic levels. A high voltage or logic level corresponds to a voltage within a predefined range of a power supply voltage level, e.g., a VDD voltage level, and a low voltage or logic level corresponds to a voltage within a predefined range of a reference voltage level, e.g., VSS.

In read operations, word line driver 120 is configured to, responsive to one or more of control signals CTRL, output a word line signal WL0-WL3 on a corresponding one of word lines WL0-WL3, e.g., corresponding to a row or column address, including one or more voltage levels, also referred to as one or more read or bias voltages WL0-WL3 in some embodiments, configured to, in combination with one or more bit line BL0-BL3 voltage levels and read interface 130 operations discussed below, detect a threshold voltage of a corresponding memory cell 112 transistor based on the corresponding work function configuration.

Read interface 130, also referred to as local I/O circuit 130 in some embodiments, is an electronic circuit configured to output bit line signals BL0-BL3 on bit lines BL0-BL3 responsive to one or more of control signals CTRL received from control circuit 140 on control signal bus CTRLB and/or from one or more circuits (not shown) external to memory circuit 100.

In read operations, read interface 130 is configured to, responsive to one or more of control signals CTRL, output a bit line signal BL0-BL3, also referred to as one or more read or bias voltages BL0-BL3 in some embodiments, on a corresponding one of bit lines BL0-BL3, e.g., corresponding to a column or row address, including one or more voltage levels configured to, in combination with the one or more word line WL0-WL3 voltage levels discussed above and read interface 130 operations discussed below, detect a threshold voltage of a corresponding memory cell 112 transistor.

Read interface 130 includes one or more signal detection circuits (not shown), e.g., current detectors and/or sense amplifiers, and is thereby configured to perform one or more read operations, e.g., measure one or more currents, voltages, or voltage differences, based on one or more signals received on one or a combination of bit lines BL0-BL3 and/or reference lines VSS, in which a threshold voltage of a selected memory cell 112 transistor is detected.

The one or more signal detection circuits are configured to determine an encoding level of a selected memory cell 112 based on the detected threshold voltage. In some embodiments, the encoding level is determined based on one or a combination of the detected threshold voltage being within one or more predetermined ranges of voltage levels, or greater and/or less than one or more predetermined voltage levels. In some embodiments, the one or more signal detection circuits are configured to determine the encoding level of the selected memory cell 112 based on one or more currents, e.g., a channel current, corresponding to one or more voltage levels of a bit line signal BL0-BL3 in combination with the gate work function configuration of the gate of the corresponding memory cell 112 transistor as discussed above.

The one or more signal detection circuits of read interface 130 are configured to generate one or more output signals, e.g., signals W1[00]-W4[11] discussed below, including a plurality of bits having values corresponding to the encoding levels of memory cells 112 corresponding to the threshold voltages.

In some embodiments, a given output signal is considered to correspond to a single memory cell 112, and a total number of bits N of the plurality of bits is given by 2>=the total number of threshold voltages of the plurality of threshold voltages of the memory cell 112. Non-limiting examples include a total number of bits N equal to two corresponding to a total of four threshold voltages, a total number of bits N equal to three corresponding to a total of eight threshold voltages, and a total number of bits N equal to four corresponding to a total of 16 threshold voltages.

Control circuit 140 is an electronic circuit configured to control operation of memory circuit 100 by generating the one or more control signals CTRL on control signal bus CTRLB and received by word line driver 120 and read interface 130 in accordance with the embodiments discussed herein. In various embodiments, control circuit 140 includes a hardware processor 142 and a non-transitory, computer-readable storage medium 144. Storage medium 144, amongst other things, is encoded with, i.e., stores, computer program code, i.e., a set of executable instructions. Execution of the instructions by hardware processor 142 represents (at least in part) a memory circuit operation tool which implements a portion or all of, e.g., method 700 discussed below with respect to FIG. 7 (hereinafter, the noted processes and/or methods).

Processor 142 is electrically coupled to non-transitory, computer-readable storage medium 144, an I/O interface, and a network via a bus (details not shown). The network interface is connected to a network (not shown) so that processor 142 and non-transitory, computer-readable storage medium 144 are capable of connecting to external elements via the network. Processor 142 is configured to execute the computer program code encoded in non-transitory, computer-readable storage medium 144 in order to cause control circuit 140 and memory circuit 100 to be usable for performing a portion or all of the noted processes and/or methods. In one or more embodiments, processor 142 is a central processing unit (CPU), a multi-processor, a distributed processing system, an application specific integrated circuit (ASIC), and/or a suitable processing unit.

In one or more embodiments, non-transitory, computer-readable storage medium 144 is an electronic, magnetic, optical, electromagnetic, infrared, and/or a semiconductor system (or apparatus or device). For example, non-transitory, computer-readable storage medium 144 includes a semiconductor or solid-state memory, a magnetic tape, a removable computer diskette, a random-access memory (RAM), a static RAM (SRAM), a dynamic RAM (DRAM), a read-only memory (ROM), a rigid magnetic disk, and/or an optical disk. In one or more embodiments using optical disks, non-transitory, computer-readable storage medium 144 includes a compact disk-read only memory (CD-ROM), a compact disk-read/write (CD-R/W), and/or a digital video disc (DVD).

In one or more embodiments, non-transitory, computer-readable storage medium 144 stores the computer program code configured to cause control circuit 140 to generate the control signals so as to be usable for performing a portion or all of the noted processes and/or methods. In one or more embodiments, non-transitory, computer-readable storage medium 144 also stores information which facilitates performing a portion or all of the noted processes and/or methods.

By the configuration discussed above, memory circuit 100 includes memory cells 112 having multiple work function configurations, and thereby multiple threshold voltages, representing encoding levels such that memory circuit 100 is capable of determining the encoding levels by detecting the threshold voltages of single IC device transistors and outputting a plurality of bits based on the encoding levels.

A given memory cell 112 is thereby capable of having increased coding density by providing multi-level coding in a smaller area compared to other approaches, e.g., those in which in which a single transistor location is used to represent binary encoding levels based on the presence or absence of a working transistor. Because memory cells 112 include a working transistor at each cell location, array 110 of memory cells 112 is also less susceptible to being decoded through reverse engineering, e.g., by optics methods, compared to other approaches, and is thereby capable of providing increased coding security.

Each of IC layout diagrams/devices 200-400 and IC layout diagrams/structures 500B-500D discussed below includes arrangements of some or all of at least one of a semiconductor substrate, an active region/area, a S/D region/structure, an MD region/segment, a gate region/structure, a metal region/segment, and/or a via region/structure, each discussed below.

A semiconductor substrate is a portion, e.g., a die, or all of a semiconductor wafer, e.g., a silicon (Si) wafer, or an epitaxial Si layer, suitable for forming one or more IC devices, e.g., IC devices 200-400. In each of the embodiments discussed below, a semiconductor substrate includes a front side within which a first subset of the features of the IC devices are formed through a first set of manufacturing processes, e.g., front-end-of-line (FEOL) processes, middle-end-of-line (MEOL) processes, and back-end-of-line (BEOL) processes, and a back side within which a second subset of the features of the IC devices are formed through a second set of manufacturing processes, e.g., backside metallization processes, performed after the first set of manufacturing processes are performed.

An active region/area, e.g., active region/area AA, is a region in an IC layout diagram included in a manufacturing process as part of defining an active area, also referred to as an oxide diffusion or definition (OD), in the semiconductor substrate, either directly or in an n-well or p-well region/area, in which one or more IC device features, e.g., a S/D structure, is formed. In some embodiments, an active area is an n-type or p-type active area of a planar transistor, a FinFET, a GAA transistor, or another transistor configuration including a gate region/structure.

In various embodiments, an active area (structure) includes one or more of a semiconductor material, e.g., silicon (Si), silicon-germanium (SiGe), silicon-carbide (SiC), or the like, a dopant material, e.g., boron (B), aluminum (Al), phosphorous (P), arsenic (As), gallium (Ga), or another suitable material.

In some embodiments, an active area is a region in an IC layout diagram included in the manufacturing process as part of defining a nano-sheet structure, e.g., a continuous volume of one or more layers of one or more semiconductor materials having either n-type or p-type doping. In various embodiments, individual nano-sheet layers include a single monolayer or multiple monolayers of a given semiconductor material.

A S/D region/structure, e.g., a S/D region structure SD, is a region in the IC layout diagram included in the manufacturing process as part of defining a S/D structure, also referred to as a semiconductor structure in some embodiments, configured to have a doping type opposite that of the corresponding active region/area. In some embodiments, a S/D region/structure is configured to have lower resistivity than an adjacent channel feature, e.g., a portion of the corresponding active region/area of a planar FET, a fin structure of a FinFET, or a gate structure of a GAA transistor. In some embodiments, a S/D region/structure includes one or more portions having doping concentrations greater than one or more doping concentrations present in the corresponding channel feature. In some embodiments, a S/D region/structure includes one or more epitaxial regions of a semiconductor material, e.g., Si, SiGe, and/or silicon-carbide SiC. A S/D region/structure, also referred to as a S/D terminal in some embodiments, may refer to a source or a drain, individually or collectively, dependent upon the context.

An MD region/segment, e.g., MD region/segment MD, is a conductive region in the IC layout diagram included in the manufacturing process as part of defining an MD segment, also referred to as a conductive segment or MD conductive line or trace, in and/or on the semiconductor substrate. In some embodiments, an MD region overlaps an active area at a location of a S/D region in the IC layout diagram, and the corresponding MD segment contacts and is electrically connected to the S/D structure of the active area.

In some embodiments, an MD segment includes a portion of at least one metal layer, e.g., a contact layer, overlying and contacting the substrate and having a thickness sufficiently small to enable formation of an insulation layer between the MD segment and an overlying metal layer, e.g., the first metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, an MD segment includes a section of the semiconductor substrate and/or an epitaxial layer having a doping level, e.g., based on an implantation process, sufficient to cause the segment to have the low resistance level. In various embodiments, a doped MD segment includes one or more dopant materials having doping concentrations of about 1*1016 per cubic centimeter (cm−3) or greater.

In some embodiments, a manufacturing process includes two MD layers, and an MD region/segment, e.g., MD region/segment MD, refers to both of the two MD layers in the manufacturing process.

A gate region/structure, e.g., a gate region/structure G or DG, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided at an adjacent gate dielectric layer.

In some embodiments, a given gate region in the IC layout diagram is included in the manufacturing process as part of defining the gate electrode including a corresponding work function configuration of a plurality of work function configurations, e.g., work function configurations WF1-WF4, as discussed above with respect to FIG. 1.

A gate dielectric layer, e.g., a gate dielectric layer of a gate structure G or DG such as a dielectric layer GD discussed below, is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

In some embodiments, a gate region/structure corresponds to a dummy gate region/structure, e.g., dummy gate region/structure DG. In some embodiments, a dummy gate region/structure includes a gate electrode electrically connected, e.g., tied-off, to one or more features, e.g., a power rail or other metal segment or an adjacent instance of a S/D region/structure such that a transistor corresponding to the dummy gate region/structure and overlapping/underlying active region/area is switched off by design. In some embodiments, a dummy gate region/structure that overlaps/overlies an edge of an active region/area is referred to as a continuous poly on oxide definition edge (CPODE) region/structure.

A metal line or region, e.g., a word line WL0-WL3 or bit line BL0-BL3, is a region in the IC layout diagram included in the manufacturing process as part of defining a metal line, or segment, including one or more conductive materials, e.g., polysilicon, copper (Cu), aluminum (Al), tungsten (W), cobalt (Co), ruthenium (Ru), or one or more other metals or other suitable materials, in a given frontside or backside metal layer of the manufacturing process.

In some embodiments, a metal region/segment corresponds to a first frontside metal layer (also referred to as a metal zero layer or frontside metal zero layer in some embodiments), or a second or higher level frontside metal layer of the manufacturing process. In some embodiments, a second frontside metal layer is referred to as a metal one layer or frontside metal one layer.

In some embodiments, a metal region/segment, e.g., reference line VSS, corresponds to a component of a power distribution network configured to distribute one or both of a power supply voltage, e.g., a power supply voltage VDD, and a reference or ground voltage, e.g., reference voltage VSS. The power distribution network component is electrically connected to one or more features, e.g., additional metal regions/segments and/or via regions/structures, configured to distribute the corresponding power supply or reference voltage and be electrically isolated from IC components outside the distribution network.

A via region/structure, e.g., a via region/structure VG or VD, is a region in the IC layout diagram included in the manufacturing process as part of defining a via structure including one or more conductive materials configured to provide an electrical connection between a first, e.g., overlying, conductive structure, e.g., a word line WL0-WL3, bit line BL0-BL3, or reference line VSS, and a second, e.g., underlying, conductive structure, e.g., a metal segment, a gate electrode of a gate structure G or DG, an instance of MD segment MD, or a S/D structure, aligned with the first conductive structure in the Z direction.

In some embodiments, a via region/structure VG corresponds to the underlying conductive structure being the gate electrode of a gate region/structure G or DG, and/or a via region/structure VD corresponds to the underlying conductive structure being a S/D region/structure or MD region/segment MD.

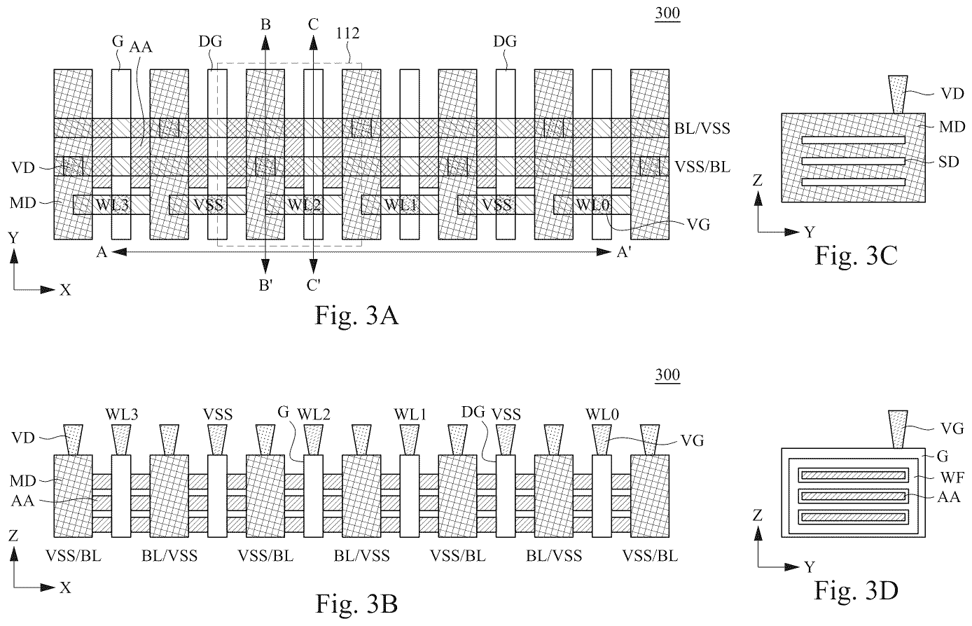

FIGS. 2A-2D, 3A-3D, and 4A-4D are plan, side, and cross-sectional views of respective IC layout diagrams/devices 200-400. FIGS. 2A, 3A, and 4A are plan views and include X and Y directions; FIGS. 2B, 3B, and 3C are side views based on line A-A′ of the corresponding FIGS. 2A, 3A, or 4A and include the X direction and a Z direction; FIGS. 2C, 3C, and 4C are cross-sectional views along line B-B′ of the corresponding FIGS. 2A, 3A, or 4A and include the Y and Z directions; and FIGS. 2D, 3D, and 4D are cross-sectional views along line C-C′ of the corresponding FIGS. 2A, 3A, or 4A and include the Y and Z directions.

IC layout diagrams/devices 200-400 include non-limiting examples of memory cell 112, discussed above with respect to FIG. 1, and correspond to n-type GAA transistors having nanosheet configurations for the purpose of illustration. IC layout diagrams/devices including memory cell 112 corresponding to other transistor types, e.g., p-type transistors and/or FinFETs or planar transistors, are within the scope of the present disclosure.

As depicted in FIGS. 2A-4D, each of IC layout diagrams/devices 200-400 includes one or more instances of each of active region/area AA, S/D region/structure SD, MD region/segment MD, via region/structure VD, gate region/structure G including work function configuration WF, dummy gate region/structure DG, via region/structure VG, bit line BL corresponding to one of bit lines BL0-BL3 discussed above, reference line VSS, and word lines WL0 and WL1. Each of IC layout diagrams/devices 300 and 400 also includes word lines WL2 and WL3. In some cases, for the purpose of clarity, not all instances of each feature are labeled in FIGS. 2A-4D.

In each of the embodiments depicted in FIGS. 2A-4D, work function configuration WF represents any one work function configuration WF of a plurality of work function configurations as discussed above with respect to FIG. 1, and illustrated in the non-limiting examples discussed below with respect to FIGS. 5A-5D.

As depicted in FIGS. 2A-2D, IC layout diagram/device 200 includes active region/area AA extending between first and second edges that intersect/underlie instances of dummy gate region/area DG. A total of four instances of gate region/structure G intersect/overlie active region/area AA, and a total of five instances of each of S/D region/structure SD and MD region/segment MD intersect/overlie active region/area AA adjacent to the instances of gate regions/structures DG and G.

Three instances of via region/structure VD overlap/overlie alternating instances of MD region/segment MD and overlap/underlie one of bit line BL or reference line VSS two instances of via region/structure VD overlap/overlie the other instances of MD region/segment MD and overlap/underlie the other of bit line BL or reference line VSS, two instances of via region/structure VG overlap/overlie instances of via gate region/structure G and overlap/underlie word line WL1, and two instances of via region/structure VG overlap/overlie instances of via gate region/structure G and overlap/underlie word line WL0.

IC layout diagram/device 200 is thereby configured to include a first instance of memory cell 112 (labeled) corresponding to a transistor including two instances of gate region/structure G coupled to word line WL1 through instances of via region/structure VG, two adjacent instances of each of S/D region/structure SD and MD region/segment MD coupled to the one of bit line BL or reference line VSS through instances of via region/structure VD, and a single instance of each of S/D region/structure SD and MD region/segment MD coupled to the other of bit line BL or reference line VSS through an instance of via region/structure VD.

A second instance of memory cell 112 (not labeled) corresponds to a transistor including two instances of gate region/structure G coupled to word line WL0 through instances of via region/structure VG, two adjacent instances of each of S/D region/structure SD and MD region/segment MD coupled to the one of bit line BL or reference line VSS through instances of via region/structure VD, and a single instance of each of S/D region/structure SD and MD region/segment MD coupled to the other of bit line BL or reference line VSS through an instance of via region/structure VD. One instance of each of S/D region/structure SD, MD segment MD, and via region/structure VD is shared by the instances of memory cell 112.

As depicted in FIGS. 2A-2D and 3A-3D, each of IC layout diagrams/devices 300 and 400 includes a first instance of active region/area AA extending between first and second instances of dummy gate region/area DG.

IC layout diagram/device 300 includes the first instance of active region/area AA extending continuously beyond the instances of dummy gate region/structure DG in the positive and negative X directions. A via region/structure VG overlaps/overlies each instance of dummy gate DG and overlaps/underlies reference line VSS such that, in operation, the portion of active area AA between the instances of dummy gate region/structure DG is electrically isolated from the extending portions by reference voltage VSS being applied to each instance of dummy gate region/structure DG.

IC layout diagram/device 400 includes the first instance of active region/area AA extending between first and second edges that intersect/underlie the instances of dummy gate region/area DG, and second and third instances of active region/area AA extending away from the first instance of active region/area AA in the positive and negative X directions beyond the instances of dummy gate region/structure DG, and thereby electrically isolated from the first instance of active region/area AA.

Each of IC layout diagrams/devices 300 and 400 includes a total of two instances of gate region/structure G that intersect/overlie an instance of active region/area AA between the instances of dummy gate region/structure DG, and a total of three instances of each of S/D region/structure SD and MD region/segment MD that intersect/overlie the instance of active region/area AA adjacent to the instances of gate regions/structures DG and G.

Two instances of via region/structure VD overlap/overlie alternating instances of MD region/segment MD and overlap/underlie one of bit line BL or reference line VSS, one instance of via region/structure VD overlaps/overlies the other instance of MD region/segment MD and overlaps/underlies the other of bit line BL or reference line VSS, one instance of via region/structure VG overlaps/overlies an instances of via gate region/structure G and overlaps/underlies word line WL2, and one instance of via region/structure VG overlaps/overlies an instance of via gate region/structure G and overlaps/underlies word line WL1.

IC layout diagram/device 200 is thereby configured to include a first instance of memory cell 112 (labeled) corresponding to a transistor including one instance of gate region/structure G coupled to word line WL2 through an instance of via region/structure VG, one adjacent instance of each of S/D region/structure SD and MD region/segment MD coupled to the one of bit line BL or reference line VSS through an instance of via region/structure VD, and one adjacent instance of each of S/D region/structure SD and MD region/segment MD coupled to the other of bit line BL or reference line VSS through an instance of via region/structure VD.

A second instance of memory cell 112 (not labeled) corresponds to a transistor including one instance of gate region/structure G coupled to word line WL1 through an instance of via region/structure VG, one adjacent instance of each of S/D region/structure SD and MD region/segment MD coupled to the one of bit line BL or reference line VSS through instances of via region/structure VD, and one adjacent instance of each of S/D region/structure SD and MD region/segment MD coupled to the other of bit line BL or reference line VSS through an instance of via region/structure VD. One instance of each of S/D region/structure SD, MD segment MD, and via region/structure VD is shared by the instances of memory cell 112.

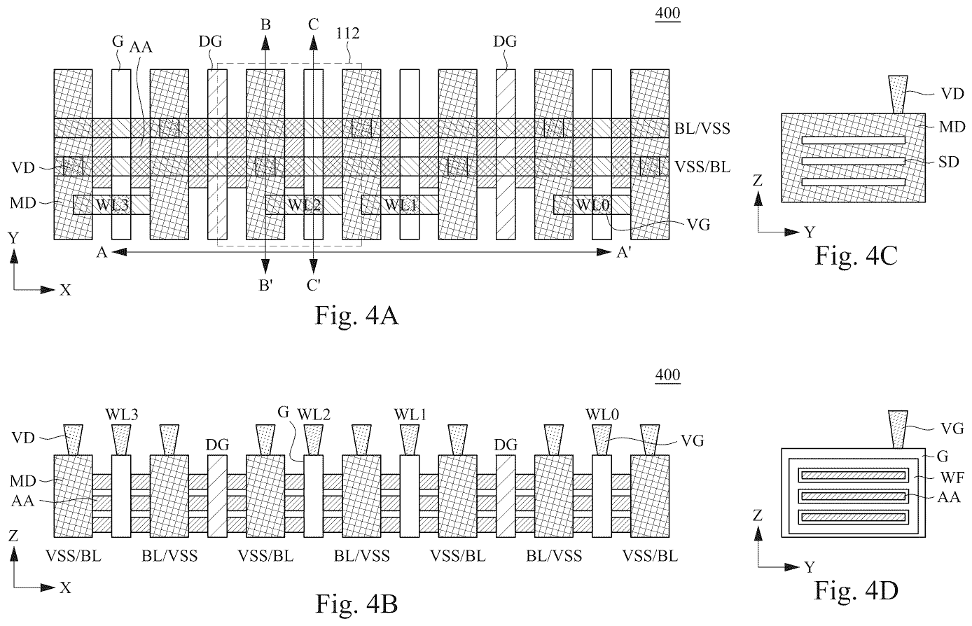

In the embodiments depicted in FIGS. 3A-4D, each of IC layout diagrams/devices 300 and 400 includes third and fourth instances of memory cell 112 corresponding to word lines WL3 and WL0 and configured similarly to the first and second instances of memory cell 112. In some embodiments, one or both of IC layout diagram/device 300 or 400 does not include one or both of the third or fourth instances of memory cell 112.

By the configuration discussed above, each of IC layout diagrams/devices 200-400 includes one or more instances of memory cell 112 having multiple work function configurations, and thereby multiple threshold voltages, representing encoding levels such that a memory circuit including one or more of IC layout diagrams/devices 200-400 is capable of realizing the benefits discussed above with respect to memory circuit 100.

In accordance with various embodiments, FIG. 5A depicts memory circuit operating parameters and FIGS. 5B-5D are cross-sectional views of IC layout diagrams/structures 500B-500D, also referred to as gate regions/structures 500B-500D in some embodiments. Each gate region/structure 500B-500D is usable as one or more instances of gate region/structure G discussed above with respect to FIGS. 2A-4D.

FIG. 5A includes a channel current Id plotted as a function of a source-drain voltage VD of a transistor, e.g., memory cell 112 discussed above, having one of threshold voltages Vth1-Vth4 corresponding to a gate work function configuration, non-limiting examples of which are depicted in FIGS. 5B-5D.

In the embodiments depicted in FIGS. 5A-5D, a total of four work function configurations WF1-WF4 (each corresponding to work function configuration WF discussed above) correspond to the total of four threshold voltages Vth1-Vth4. The threshold voltages Vth1-Vth4 are associated with respective two-bit signals W1[00]-W4[11]. Other numbers of work function configurations, threshold voltages, and signal bits are within the scope of the present disclosure. In some embodiments, signals W1[00]-W4[11] are examples of read interface 130 output signals discussed above with respect to FIG. 1.

In the embodiment depicted in FIG. 5A, increasing threshold voltages Vth1-Vth4 correspond to increasing signal values [00]-[11]. Other relationships between threshold voltages and signal values, e.g., increasing threshold voltages corresponding to decreasing signal values, are within the scope of the present disclosure.

As depicted in FIGS. 5B-5D, each of gate regions/structures 500B-500D includes a gate region/structure G including one or more work function configurations WF1-WF4 adjacent to one or more gate dielectric layers GD, each adjacent to a channel region of a corresponding active region/area AA. Work function configurations WF1-WF4 correspond to respective threshold voltages Vth1-Vth4 and signals W1[00]-W4[11].

As depicted in FIGS. 5B-5D, gate region/structure 500B corresponds to a nanosheet configuration of a GAA transistor, gate region/structure 500C corresponds to a gate configuration of a FinFET, and gate region/structure 500D corresponds to a gate configuration of a planar transistor.

As illustrated in FIG. 5A, an IC layout diagram/device, e.g., IC layout diagram/device 200-400 discussed above, including one or more of gate regions/structures 500B-500D is thereby capable of realizing the benefits discussed above with respect to memory circuit 100 and IC layout diagrams/devices 200-400.

FIG. 6 is a flowchart of method 600 of operating a memory circuit, in accordance with some embodiments. Method 600 is usable with a memory circuit, e.g., memory circuit 100 including instances of memory cell 112, discussed above with respect to FIGS. 1-5D. In some embodiments, the operations of method 600 are a subset of operations of a method of operating an IC, e.g., a SOC.

In some embodiments, the operations of method 600 are repeated, e.g., sequentially with respect to a plurality of memory cells, e.g., multiple instances of memory cell 112 discussed above with respect to FIGS. 1-5D. In some embodiments, the operations of method 600 are part of an initialization sequence of an IC or IC package.

The sequence in which the operations of method 600 are depicted in FIG. 6 is for illustration only; the operations of method 600 are capable of being executed in sequences that differ from that depicted in FIG. 6. In some embodiments, operations in addition to those depicted in FIG. 6 are performed before, between, during, and/or after the operations depicted in FIG. 6.

At operation 602, in some embodiments, a ROM cell of a memory circuit is selected. Selecting the ROM cell includes outputting a combination of word line and bit line signals in accordance with one or more location identifiers, e.g., addresses, corresponding to the ROM cell.

In some embodiments, selecting the ROM cell includes selecting an instance of memory cell 112 of memory circuit 100 discussed above with respect to FIGS. 1-5D.

At operation 604, a threshold voltage of the selected memory cell is detected. Detecting the threshold voltage includes detecting one predetermined threshold voltage of a plurality of predetermined threshold voltages, each based on a corresponding gate work function configuration of a plurality of work function configurations.

In some embodiments, detecting the threshold voltage includes detecting the threshold voltage of an instance of memory cell 112 including a gate G work function configuration as discussed above with respect to FIGS. 1-5D. In some embodiments, detecting the threshold voltage includes detecting the threshold voltage based on work function configuration WF discussed above with respect to FIGS. 2A-4D and/or work function configuration WF1-WF4 discussed above with respect to FIGS. 5A-5D.

In some embodiments, detecting the threshold voltage includes using a read circuit of the memory circuit, e.g., read interface 130 discussed above with respect to FIG. 1.

In some embodiments, detecting the threshold voltage includes detecting one of threshold voltages Vth1-Vth4 discussed above with respect to FIGS. 5A-5D.

At operation 606, in some embodiments, a plurality of bits is output having a value based on the detected threshold voltage of the selected memory cell. Outputting the plurality of bits includes outputting a number of bits corresponding to a number of possible predetermined threshold voltages of the selected memory cell, e.g., as discussed above with respect to FIG. 1.

In some embodiments, outputting the plurality of bits includes using a read circuit of the memory circuit, e.g., read interface 130 discussed above with respect to FIG. 1.

In some embodiments, outputting the plurality of bits includes outputting one of signals W1[00]-W4[11] discussed above with respect to FIGS. 5A-5D.

In some embodiments, outputting the plurality of bits includes outputting the plurality of bits to a circuit external to the memory circuit, e.g., a SOC or other IC.

By executing some or all of the operations of method 600, an encoding of a ROM cell of a memory circuit is determined and a plurality of bits is output having a value based on a work function configuration of the ROM cell, thereby achieving the benefits discussed above with respect to memory circuit 100, IC layout diagrams/devices 200-400, and IC layout diagrams/structures 500B-500D.

FIG. 7 is a flowchart of method 700 of manufacturing an IC device, in accordance with some embodiments. Method 700 is operable to form some or all of one or more of IC devices 200-400 discussed above with respect to FIGS. 1-5D.

In some embodiments, performing some or all of the operations of method 700 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor wafer.

In some embodiments, the operations of method 700 are performed in the order depicted in FIG. 7. In some embodiments, the operations of method 700 are performed in an order other than the order depicted in FIG. 7. In some embodiments, one or more additional operations are performed before, during, and/or after the operations of method 700. In some embodiments, performing some or all of the operations of method 700 includes performing one or more operations as discussed below with respect to IC manufacturing system 1000 and FIG. 10.

At operation 702, an active area is formed in a semiconductor substrate. Forming the active area includes forming the active area extending in a first direction between first and second edges. In some embodiments, forming the active area includes forming an instance of active area AA discussed above with respect to FIGS. 1-5D.

In some embodiments, forming the active area includes forming a plurality of active areas, e.g., corresponding to a memory cell array such as array 110 discussed above with respect to FIG. 1.

In some embodiments, forming the active area includes forming the active area configured in accordance with a GAA transistor, FinFET, or a planar transistor, e.g., as discussed above with respect to FIGS. 1-5D.

In some embodiments, forming the active area includes performing a plurality of manufacturing processes including one or more of a lithography, diffusion, implantation, deposition, etching, planarizing, or other suitable operation.

At operation 704, a first transistor including a first gate work function configuration and a second transistor including a second gate work function configuration different from the first work function configuration are constructed on the active area. Constructing the first and second transistors includes constructing the corresponding gates having the first and second work function configurations corresponding to threshold voltages of each of the first and second transistors.

In some embodiments, constructing the first and second transistors includes constructing instances of memory cell 112 discussed above with respect to FIGS. 1-5D.

In some embodiments, constructing the first and second transistors includes constructing an array of memory cells, e.g., array 110 discussed above with respect to FIG. 1.

In some embodiments, constructing the first and second transistors includes constructing one or more of IC devices 200-400 including instances of memory cell 112 as discussed above with respect to FIGS. 2A-4D.

In some embodiments, constructing the gates of the first and second transistors includes constructing one or more of gate structures G discussed above with respect to FIGS. 2A-4D and/or gate structures 500B-500D discussed above with respect to FIGS. 5A-5D.

In some embodiments, constructing the first and second transistors includes constructing GAA transistors, FinFETs, or planar transistors.

In some embodiments, constructing the first and second transistors including the first and second work function configurations includes constructing the first and second transistors including instances of work function configuration WF discussed above with respect to FIGS. 2A-4D and/or work function configurations WF1-WF4 discussed above with respect to FIGS. 5A-5D.

In some embodiments, constructing the first and second transistors including the first and second work function configurations includes performing a plurality of manufacturing processes including one or more of a lithography, diffusion, implantation, deposition, plasma treatment, etching, planarizing, spin coating, soft-baking, exposure, post-baking, developing, rinsing, drying, or other suitable operation.

At operation 706, electrical connections are formed from the first and second transistors to at least one of a word line, a bit line, and a reference line. Forming the electrical connections includes forming via structures on each transistor gate and S/D terminal and forming at least one corresponding word line, bit line, and reference line on the via structures such that each of the first and second transistor is a working transistor.

In some embodiments, forming the electrical connections includes forming some or all of via structures VG on gate structures G, via structures VD on MD segments MD, word lines WL0-WL3 on gate via structures VG, bit lines BL0-BL3 and reference lines VSS on via structures VD, as discussed above with respect to FIGS. 1-5D.

In some embodiments, forming the electrical connections includes forming the electrical connections to memory circuit components, e.g., word line driver 120 and read interface 130 discussed above with respect to FIG. 1.

In some embodiments, forming the electrical connections includes performing a plurality of manufacturing operations including depositing and patterning one or more photoresist layers, performing one or more etching processes, and performing one or more deposition processes whereby one or more conductive materials are configured to form a plurality of continuous, low resistance structures.

By performing some or all of the operations of method 700, an IC device is manufactured in which first and second transistors include differing work function configurations, thereby enabling the realization of the benefits discussed above with respect to memory circuit 100, IC devices 200-400, and IC structures 500B-500D.

FIG. 8 is a flowchart of method 800 of generating an IC layout diagram, e.g., one or more of IC layout diagrams 200-400 discussed above with respect to FIGS. 2A-5D, in accordance with some embodiments.

In some embodiments, generating the IC layout diagram includes generating the IC layout diagram corresponding to an IC device, e.g., IC device 200-400 discussed above with respect to FIGS. 2A-5D, manufactured based on the generated IC layout diagram.

In some embodiments, some or all of method 800 is executed by a processor of a computer, e.g., a processor 902 of an IC layout diagram generation system 900, discussed below with respect to FIG. 9.

Some or all of the operations of method 800 are capable of being performed as part of a design procedure performed in a design house, e.g., a design house 1020 discussed below with respect to FIG. 10.

In some embodiments, the operations of method 800 are performed in the order depicted in FIG. 8. In some embodiments, the operations of method 800 are performed simultaneously and/or in an order other than the order depicted in FIG. 8. In some embodiments, one or more operations are performed before, between, during, and/or after performing one or more operations of method 800.

At operation 802, in some embodiments, a plurality of work function configurations is assigned in accordance with a ROM encoding pattern. In some embodiments, assigning the plurality of work function configurations includes obtaining ROM cells from a cell library, e.g., cell library 907 discussed below with respect to FIG. 9, in which each ROM cell includes a specific work function configuration.

In some embodiments, assigning the plurality of work function configurations includes assigning instances of work function configuration WF discussed above with respect to FIGS. 2A-4D and/or work function configurations WF1-WF4 discussed above with respect to FIGS. 5A-5D.

In some embodiments, assigning the plurality of work function configurations in accordance with the ROM encoding pattern includes the ROM encoding pattern corresponding to an array, e.g., array 110 discussed above with respect to FIG. 1.

In some embodiments, assigning the plurality of work function configurations includes performing a compile operation to generate the ROM encoding pattern.

At operation 804, first and second transistors are arranged including differing work function configurations of the plurality of work function configurations. In some embodiments, arranging the first and second transistors includes arranging one or more of IC layout diagrams 200-400 including instances of memory cell 112 as discussed above with respect to FIGS. 2A-4D.

In some embodiments, arranging the first and second transistors includes arranging one or more of gate regions G discussed above with respect to FIGS. 2A-4D and/or gate regions 500B-500D discussed above with respect to FIGS. 5A-5D.

In some embodiments, arranging the first and second transistors includes arranging GAA transistors, FinFETs, or planar transistors.

At operation 806, the first and second transistors are overlapped with via and metal regions. Overlapping the via and metal regions includes overlaying via regions on each transistor gate region and S/D region and overlapping the via regions with at least one corresponding word line, bit line, and reference line such that each of the first and second transistor is a working transistor.

In some embodiments, overlapping the via and metal regions includes overlapping some or all of via regions VG with gate regions G, via regions VD with MD regions MD, word lines WL0-WL3 with gate via regions VG, bit lines BL0-BL3 and reference lines VSS with via regions VD, as discussed above with respect to FIGS. 1-5D.

In some embodiments, overlapping the via and metal regions includes arranging electrical connections to memory circuit components, e.g., word line driver 120 and read interface 130 discussed above with respect to FIG. 1.

At operation 808, in some embodiments, the IC layout diagram including the first and second transistors is stored in a storage device. In some embodiments, storing the IC layout diagram in the storage device includes storing one or more of IC layout diagrams 200-400, discussed above with respect to FIGS. 2A-5D, in the storage device.

In some embodiments, storing the IC layout diagram in the storage device includes storing the IC layout diagram in a non-volatile, computer-readable memory or a database, and/or includes storing the IC layout diagram over a network. In some embodiments, storing the IC layout diagram in the storage device includes storing the IC layout diagram in layout diagrams 909 and/or over network 914 of IC layout diagram generation system 900, discussed below with respect to FIG. 9.

At operation 810, in some embodiments, one or more manufacturing operations, one or more lithographic exposures, are performed based on the IC layout diagram. Non-limiting examples of performing one or more manufacturing operations, e.g., one or more lithographic exposures, based on the IC layout diagram are discussed above with respect to FIG. 7 and below with respect to FIG. 10.

By executing some or all of the operations of method 800, an IC layout diagram is generated corresponding to an IC device in which first and second transistors include differing work function configurations, thereby enabling the realization of the benefits discussed above with respect to memory circuit 100, IC devices 200-400, and IC structures 500B-500D.

FIG. 9 is a block diagram of IC layout diagram generation system 900, in accordance with some embodiments. Methods described herein of designing IC layout diagrams in accordance with one or more embodiments are implementable, for example, using IC layout diagram generation system 900, in accordance with some embodiments.

In some embodiments, IC layout diagram generation system 900 is a general purpose computing device including a hardware processor 902 and a non-transitory, computer-readable storage medium 904. Storage medium 904, amongst other things, is encoded with, i.e., stores, computer program code 906, i.e., a set of executable instructions. Execution of instructions 906 by hardware processor 902 represents (at least in part) an electronic design automation (EDA) tool which implements a portion or all of a method, e.g., method 800 of generating an IC layout diagram described above with respect to FIG. 8 (hereinafter, the noted processes and/or methods).

Processor 902 is electrically coupled to computer-readable storage medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable storage medium 904 are capable of connecting to external elements via network 914. Processor 902 is configured to execute computer program code 906 encoded in computer-readable storage medium 904 in order to cause IC layout diagram generation system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable storage medium 904 is an electronic, magnetic, optical, electromagnetic, infrared, and/or a semiconductor system (or apparatus or device). For example, computer-readable storage medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 904 includes a compact disk-read only memory (CD-ROM), a compact disk-read/write (CD-R/W), and/or a digital video disc (DVD).

In one or more embodiments, computer-readable storage medium 904 stores computer program code 906 configured to cause IC layout diagram generation system 900 (where such execution represents (at least in part) the EDA tool) to be usable for performing a portion or all of the noted processes and/or methods. In one or more embodiments, computer-readable storage medium 904 also stores information which facilitates performing a portion or all of the noted processes and/or methods.

In one or more embodiments, computer-readable storage medium 904 stores cell library 907 of cells including such cells as disclosed herein, e.g., memory cell 112 of IC layout diagrams 200-400 discussed above with respect to FIGS. 1-5D.

In one or more embodiments, computer-readable storage medium 904 stores layout diagrams 909 including such IC layout diagrams as disclosed herein, e.g., IC layout diagrams 200-400 discussed above with respect to FIGS. 1-5D.

IC layout diagram generation system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

IC layout diagram generation system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 900.

IC layout diagram generation system 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. IC layout diagram generation system 900 is configured to receive information related to a UI through I/O interface 910. The information is stored in computer-readable medium 904 as user interface (UI) 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 10 is a block diagram of IC manufacturing system 1000, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns, e.g., one or more of IC layout diagrams 200-400 discussed above with respect to FIGS. 1-5D. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place and route. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (RDF). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for limitations during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes wafer fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some embodiments, an IC device includes a first transistor including a first gate coupled to a first word line and including a first work function configuration, a first metal-like defined (MD) segment adjacent to the first gate and coupled to one of a bit line or a reference line, and a second MD segment adjacent to the first gate and coupled to the other of the bit line or the reference line, and a second transistor including a second gate coupled to a second word line and including a second work function configuration different from the first work function configuration, the second MD segment adjacent to the second gate, and a third MD segment adjacent to the second gate and coupled to the one of the bit line or the reference line.

In some embodiments, a ROM circuit includes a plurality of word lines, a plurality of bit lines, a plurality of reference lines, a plurality of ROM cells, wherein each ROM cell of the plurality of ROM cells includes a transistor including a first gate coupled to a corresponding word line of the plurality of word lines and including a corresponding work function configuration of a plurality of work function configurations, a first MD segment adjacent to the first gate and coupled to a corresponding bit line of the plurality of bit lines and a second MD segment adjacent to the first gate and coupled to a corresponding reference line of the plurality of reference lines, and a sense amplifier selectively coupled to each ROM cell of the plurality of ROM cells, wherein the sense amplifier is configured to output a plurality of bits having values based on the work function configurations of the plurality of work function configurations.

In some embodiments, a method of manufacturing an IC device includes constructing a first transistor, constructing the first transistor including constructing a first gate comprising a first work function configuration and forming first and second MD segments adjacent to the first gate, constructing a second transistor, constructing the second transistor including constructing a second gate adjacent to the second MD segment and comprising a second work function configuration different from the first work function configuration and forming a third MD segment adjacent to the second gate, forming first through fifth via structures on the respective first through third MD segments and first and second gates, forming one of a bit line or a reference line on each of the first and third via structures and the other of the bit line or the reference line on the second via structure, and forming first and second word lines on the respective fourth and fifth via structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
a first transistor comprising:
a first gate coupled to a first word line and comprising a first work function configuration;
a first metal-like defined (MD) segment adjacent to the first gate and coupled to one of a bit line or a reference line; and
a second MD segment adjacent to the first gate and coupled to the other of the bit line or the reference line; and
a second transistor comprising:
a second gate coupled to a second word line and comprising a second work function configuration different from the first work function configuration,
the second MD segment adjacent to the second gate; and
a third MD segment adjacent to the second gate and coupled to the one of the bit line or the reference line.

2. The IC device of claim 1, wherein
the first transistor further comprises:
a third gate adjacent to the first MD segment and coupled to the first word line; and
a fourth MD segment adjacent to the third gate and coupled to the other of the bit line or the reference line, and the second transistor further comprises:
a fourth gate adjacent to the third MD segment and coupled to the second word line; and
a fifth MD segment adjacent to the fourth gate and coupled to the other of the bit line or the reference line.

3. The IC device of claim 2, further comprising:
an active area extending between a first edge adjacent to the fourth MD segment and a second edge adjacent to the fifth MD segment;
a fifth gate overlying the first edge; and
a sixth gate overlying the second edge,
wherein the first through fifth MD segments are positioned on the active area between the fifth and sixth gates.

4. The IC device of claim 1, further comprising:
an active area;
a third gate overlying the active area adjacent to the first MD segment and coupled to the reference line; and
a fourth gate overlying the active area adjacent to the third MD segment and coupled to the reference line,
wherein the first through third MD segments are positioned on the active area between the third and fourth gates.

5. The IC device of claim 1, further comprising:
an active area extending between a first edge adjacent to the first MD segment and a second edge adjacent to the third MD segment;
a third gate overlying the first edge; and
a fourth gate overlying the second edge,
wherein the first through third MD segments are positioned on the active area between the third and fourth gates.

6. The IC device of claim 1, further comprising:
a first via structure extending between the first MD segment and the one of the bit line or the reference line;
a second via structure extending between the second MD segment and the other of the bit line or the reference line; and
a third via structure extending between the third MD segment and the one of the bit line or the reference line.

7. The IC device of claim 1, wherein each of the first and second transistors comprises:
a gate-all-around (GAA) transistor,
a fin field-effect transistor (FinFET), or
a planar transistor.

8. A read-only memory (ROM) circuit comprising:
a plurality of word lines;
a plurality of bit lines;
a plurality of reference lines;
a plurality of ROM cells, wherein each ROM cell of the plurality of ROM cells comprises a transistor comprising:
a first gate coupled to a corresponding word line of the plurality of word lines and comprising a corresponding work function configuration of a plurality of work function configurations;
a first metal-like defined (MD) segment adjacent to the first gate and coupled to a corresponding bit line of the plurality of bit lines; and
a second MD segment adjacent to the first gate and coupled to a corresponding reference line of the plurality of reference lines; and
a sense amplifier selectively coupled to each ROM cell of the plurality of ROM cells,
wherein the sense amplifier is configured to output a plurality of bits having values based on the work function configurations of the plurality of work function configurations.

9. The ROM circuit of claim 8, wherein
a total number of the work function configurations of the plurality of work function configurations is equal to four, and
a total number of bits of the plurality of bits is equal to two.

10. The ROM circuit of claim 8, wherein the transistor of each ROM cell of the plurality of ROM cells further comprises:
a second gate coupled to the corresponding word line of the plurality of word lines; and
a third MD segment adjacent to the second gate,
wherein either
the second gate is adjacent to the first MD segment and the third MD segment is coupled to the corresponding reference line of the plurality of reference lines, or
the second gate is adjacent to the second MD segment and the third MD segment is coupled to the corresponding bit line of the plurality of bit lines.

11. The ROM circuit of claim 8, wherein each ROM cell of the plurality of ROM cells further comprises:
a second gate adjacent to one of the first or second MD segments and coupled to the corresponding reference line of the plurality of reference lines.

12. The ROM circuit of claim 8, wherein each ROM cell of the plurality of ROM cells further comprises:
a dummy gate adjacent to one of the first or second MD segments.

13. The ROM circuit of claim 8, wherein each ROM cell of the plurality of ROM cells further comprises:
a first via structure extending between the first MD segment and the corresponding bit line of the plurality of bit lines; and
a second via structure extending between the second MD segment and the corresponding reference line of the plurality of reference lines.

14. The ROM circuit of claim 8, wherein the transistor of each ROM cell of the plurality of ROM cells comprises:
a gate-all-around (GAA) transistor,
a fin field-effect transistor (FinFET), or
a planar transistor.

15. A method of manufacturing an integrated circuit (IC) device, the method comprising:
constructing a first transistor, the constructing the first transistor comprising:
constructing a first gate comprising a first work function configuration; and
forming first and second metal-like defined (MD) segments adjacent to the first gate;
constructing a second transistor, the constructing the second transistor comprising:
constructing a second gate adjacent to the second MD segment and comprising a second work function configuration different from the first work function configuration; and
forming a third MD segment adjacent to the second gate;
forming first through fifth via structures on the respective first through third MD segments and first and second gates;
forming one of a bit line or a reference line on each of the first and third via structures and the other of the bit line or the reference line on the second via structure; and
forming first and second word lines on the respective fourth and fifth via structures.

16. The method of claim 15, wherein
the constructing the first transistor further comprises:
constructing a third gate adjacent to the first MD segment; and
forming a fourth MD segment adjacent to the third gate,
the constructing the second transistor further comprises:
constructing a fourth gate adjacent to the third MD segment; and
forming a fifth MD segment adjacent to the fourth gate,
the forming the first through fifth via structures further comprises forming sixth through ninth via structures on the respective fourth and fifth MD segments and third and fourth gates;
the forming the other of the bit line or the reference line further comprises forming the other of the bit line or the reference line on each of the sixth and seventh via structures; and
the forming the first and second word lines further comprises forming the first and second word lines on the respective eighth and ninth via structures.

17. The method of claim 16, wherein
the forming the first through fifth MD segments comprises forming the first through fifth MD segments on an active area extending between a first edge adjacent to the fourth MD segment and a second edge adjacent to the fifth MD segment, and
the method further comprises constructing fifth and sixth gates overlying the first and second edges.

18. The method of claim 15, wherein
the forming the first through third MD segments comprises forming the first through third MD segments on an active area, and
the method further comprises:
constructing a third gate overlying the active area adjacent to the first MD segment;
constructing a fourth gate overlying the active area adjacent to the third MD segment; and
constructing electrical connections between each of the third and fourth gates and the reference line.

19. The method of claim 15, wherein
the forming the first through third MD segments comprises forming the first through third MD segments on an active area extending between a first edge adjacent to the first MD segment and a second edge adjacent to the third MD segment, and
the method further comprises constructing third and fourth gates overlying the first and second edges.

20. The method of claim 15, wherein the constructing the first and second transistors comprises constructing:
gate-all-around (GAA) transistors,
fin field-effect transistors (FinFETs), or
planar transistors.
